(19) United States
(12) Patent Application Publication
(10) Pub. No.: US 2026/0259274 A1
(43) Pub. Date: Sep. 3, 2026

(54) Battery Diagnosis Apparatus and Operating Method Thereof

(71) Applicant: LG Energy Solution, Ltd., Seoul (KR)

(72) Inventors: Gyu Yeol Lee, Daejeon (KR); Ju Young Kim, Daejeon (KR); Yeon Do Park, Daejeon (KR)

(73) Assignee: LG Energy Solution, Ltd., Seoul (KR)

(21) Appl. No.: 19/159,790

(22) PCT Filed: May 21, 2024
(86) PCT No.: PCT/IB2024/054917

§ 371 Date: Aug. 26, 2025

(30) Foreign Application Priority Data
Apr. 5, 2023 (KR) 10-2023-0045021
Apr. 4, 2024 (KR) 10-2024-0046226

(51) Int. Cl. G01R 31/389; G01R 31/396; H01M 10/42

(52) U.S. Cl. CPC G01R 31/389; G01R 31/396; H01M 10/4285

(57) ABSTRACT

The technology generally relates to managing battery cells based on impedance data measured at a plurality of measurement points of an electrode lead of a battery cell and diagnosing a position and degree of an electrode defect based on impedance data measured at a plurality of measurement points of an electrode lead of a battery cell.

### CROSS-REFERENCE TO RELATED APPLICATIONS

This application is a national phase entry under 35 U.S.C. § 371 of International Application No. PCT/IB 2024/054917 filed on May 21, 2024, which claims priority to Korean Patent Application No. 10-2023-0045021, filed on Apr. 5, 2023, and Korean Patent Application No. 10-2024-0046226, filed on Apr. 4, 2024, all of which are incorporated herein by reference.

### BACKGROUND

Secondary batteries are chargeable/dischargeable batteries and may include nickel (Ni)/cadmium (Cd) batteries, Ni/metal hydride (MH) batteries, and lithium-ion batteries. Among the secondary batteries, a lithium-ion battery has a higher energy density than the Ni/Cd batteries, Ni/MH batteries, etc. Moreover, the lithium-ion battery may be manufactured to be small and lightweight, such that the lithium-ion battery can be used as a power source of mobile devices. In addition, the lithium-ion battery is attracting attention as a next-generation energy storage medium for use as a power source of electric vehicles.

An electric vehicle includes a battery that is charged and discharged. The battery may undergo internal deformation and denaturation through various charges/discharges in production and use phases, such that physical and chemical characteristics of the battery change. Thus, the state of the battery may be managed to diagnose any degradation or deterioration of the battery.

To manage the state of the battery, a test may be conducted on the battery. For example, electrochemical impedance spectroscopy (EIS), may detect an abnormal battery state based on an impedance of an inspection target battery, measured in a specific frequency domain, e.g., a resonant-frequency domain. However, EIS utilizing measurements in a resonant-frequency domain may have low diagnosis accuracy.

### BRIEF SUMMARY

Aspects of the disclosure are directed to managing battery cells based on impedance data measured at a plurality of measurement points of an electrode lead of a battery cell. Aspects of the disclosure are further directed to diagnosing a position and degree of an electrode defect based on impedance data measured at a plurality of measurement points of an electrode lead of a battery cell.

Aspects of the disclosure provide for a battery diagnosis apparatus including: an interface configured to obtain a frequency-specific impedance of a voltage applied between each of a plurality of measurement points of a first electrode lead of an inspection target battery cell and a second electrode lead of the battery cell; and one or more processors configured to diagnose a state of the battery cell, based on a first impedance that is an impedance between a first point among the plurality of measurement points and the second electrode lead, a second impedance that is an impedance between a second point among the plurality of measurement points and the second electrode lead, and a first impedance variance that is a difference between the first impedance and the second impedance.

In some examples, the first point and the second point may be spaced apart from each other in a second direction intersecting a first direction in which the first electrode lead protrudes from the battery cell.

In some examples, the first point and the second point may be positioned along a straight line in the second direction.

In some examples, the one or more processors may be further configured to compare the first impedance, the second impedance, and the first impedance variance with a predetermined threshold value and diagnose the battery cell as being in an abnormal state when at least one of the first impedance, the second impedance, and the first impedance variance is greater than the predetermined threshold value.

In some examples, the one or more processors may be further configured to determine the predetermined threshold value based on the frequency-specific impedance measured at each of a first point of a normal battery cell corresponding to the first point and a second point of the normal battery cell corresponding to the second point.

In some examples, the one or more processors may be further configured to diagnose the state of the battery cell, based on a third impedance that is an impedance between a third point among the plurality of measurement points and the second electrode lead, a second impedance variance that is a difference between the second impedance and the third impedance, and a third impedance variance that is a difference between the first impedance and the third impedance.

In some examples, the first point may be spaced from the second point by a first interval in the second direction intersecting the first direction in which the first electrode lead protrudes from the battery cell, and the third point may be spaced from the second point by the first interval in a direction opposite to the second direction.

In some examples, the one or more processors may be further configured to diagnose a position where a defect occurs in the inspection target battery cell, based on a sign of the first impedance variance.

In some examples, the one or more processors may be further configured to diagnose that the defect occurs at the first point in the inspection target battery cell, when the first impedance variance is a positive number and diagnose that the defect occurs at the second point in the inspection target battery cell, when the first impedance variance is a negative number.

In some examples, the one or more processors may be further configured to diagnose that a degree of the defect occurring in the inspection target battery cell based on at least one of a magnitude of the first impedance, a magnitude of the second impedance, or a magnitude of the first impedance variance.

Aspects of the disclosure provide for an operating method of a battery diagnosis apparatus including: obtaining a frequency-specific impedance of a voltage applied between each of a plurality of measurement points of a first electrode lead of an inspection target battery cell and a second electrode lead of the battery cell; and diagnosing a state of the battery cell, based on a first impedance that is an impedance between a first point among the plurality of measurement points and the second electrode lead, a second impedance that is an impedance between a second point among the plurality of measurement points and the second electrode lead, and a first impedance variance that is a difference between the first impedance and the second impedance.

In some examples, the first point and the second point may be spaced apart from each other in a second direction intersecting a first direction in which the first electrode lead protrudes from the battery cell.

In some examples, the first point and the second point may be positioned along a straight line in the second direction.

In some examples, the diagnosing may include comparing the first impedance, the second impedance, and the first impedance variance with a predetermined threshold value and diagnosing the battery cell as being in an abnormal state when at least one of the first impedance, the second impedance, and the first impedance variance is greater than the predetermined threshold value.

In some examples, the diagnosing may include determining the predetermined threshold value based on the frequency-specific impedance measured at each of a first point of a normal battery cell corresponding to the first point and a second point of the normal battery cell corresponding to the second point.

In some examples, the diagnosing may include diagnosing the state of the battery cell, based on a third impedance that is an impedance between a third point among the plurality of measurement points and the second electrode lead, a second impedance variance that is a difference between the second impedance and the third impedance, and a third impedance variance that is a difference between the first impedance and the third impedance.

In some examples, the first point may be spaced from the second point by a first interval in the second direction intersecting the first direction in which the first electrode lead protrudes from the battery cell, and the third point may be spaced from the second point by the first interval in a direction opposite to the second direction.

In some examples, the diagnosing may include diagnosing a position where a defect occurs in the inspection target battery cell, based on a sign of the first impedance variance.

In some examples, the diagnosing of the position at which the defect occurs may include diagnosing that the defect occurs at the first point in the inspection target battery cell, when the first impedance variance is a positive number and diagnose that the defect occurs at the second point in the inspection target battery cell, when the first impedance variance is a negative number.

In some examples, the diagnosing may include diagnosing that a degree of the defect occurring in the inspection target battery cell based on at least one of a magnitude of the first impedance, a magnitude of the second impedance, or a magnitude of the first impedance variance.

### BRIEF DESCRIPTION OF DRAWINGS

FIG. 1 is a block diagram of a battery pack according to aspects of the disclosure.

FIG. 2 is a block diagram of a battery diagnosis apparatus according to aspects of the disclosure.

FIG. 3 is a diagram showing an inner side of a battery cell according to aspects of the disclosure.

FIG. 4 is a diagram showing a method of measuring an impedance of an electrode lead of a battery cell according to aspects of the disclosure.

FIG. 5 is a graph showing frequency vs reactance for diagnosing an abnormal battery cell according to aspects of the disclosure.

FIG. 6 is a flowchart of an operating method of a battery diagnosis apparatus according to aspects of the disclosure.

FIG. 7 is a block diagram showing a computing system according to aspects of the disclosure.

### DETAILED DESCRIPTION

The disclosure may be modified in various forms and have various examples, and specific examples thereof are shown by way of drawings and description below. It should be understood, however, that there is no intent to limit the disclosure to the specific examples, but on the contrary, the disclosure is to cover all modifications, equivalents, and alternatives falling within the spirit and technical scope of the disclosure. Like reference numerals refer to like elements throughout the description of the figures.

It will be understood that, although the terms such as first, second, A, B, and the like may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes combinations of a plurality of associated listed items or any of the plurality of associated listed items.

It will be understood that when an element is referred to as being “connected” to another element, it can be directly connected to the other element or an intervening element may be present.

The terms used herein are for the purpose of describing specific examples only and are not intended to limit the disclosure. As used herein, the singular forms “a”, “an” and “the” are intended to include the plural forms as well, unless the context clearly indicates otherwise. It will be further understood that the terms “comprises”, “comprising”, “includes”, “including” and/or “having”, when used herein, specify the presence of stated features, integers, steps, operations, constitutional elements, components and/or combinations thereof, but do not preclude the presence or addition of one or more other features, integers, steps, operations, constitutional elements, components, and/or combinations thereof.

Aspects of the disclosure may be provided in a computer program product. The computer program product may be traded as a product between a seller and a buyer. The computer program product may be distributed in the form of a machine-readable storage medium, e.g., compact disc read only memory (CD-ROM)), or be distributed, e.g., downloaded or uploaded, online via an application store, or be distributed between two user devices directly. If distributed online, at least part of the computer program product may be temporarily generated or at least temporarily stored in the machine-readable storage medium, such as memory of the manufacturer's server, a server of the application store, or a relay server.

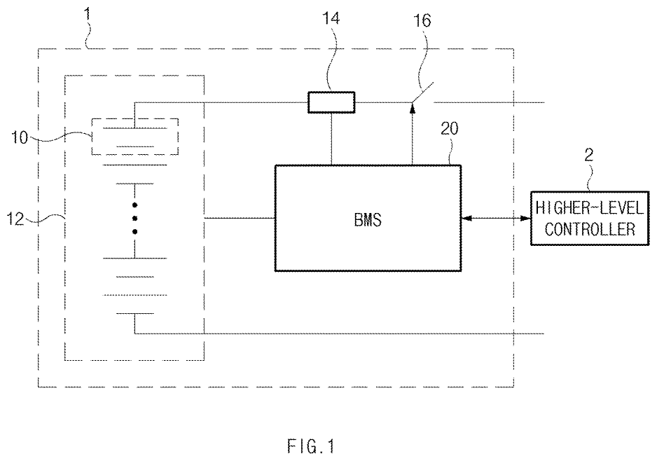

FIG. 1 is a block diagram of a battery pack according to aspects of the disclosure. The battery pack 1 may include a battery unit 12, a sensor unit 14, a switching unit 16, and a battery management system (BMS) 20. The battery pack 1 may include the battery unit 12, the sensor unit 14, the switching unit 16, and the BMS 20.

The battery unit 12 may be electrically connected to a target device (not shown) to supply power to the target device. The target device may include an electrical, electronic, or mechanical device that operates by receiving power from the battery pack 1. For example, the target device may be an electric vehicle (EV) or an energy storage system (ESS).

The battery unit 12 may include at least one chargeable/dischargeable battery cell 10. The battery cell 10 may be a basic unit of a battery cell available through charging/discharging of electric energy. For example, the battery cell 10 may be a lithium ion (Li-ion) battery, an Li-ion polymer battery, a nickel-cadmium (Ni—Cd) battery, a nickel hydrogen (Ni—MH) battery. The battery cells 10 may be connected in series or in parallel. For example, the battery unit 12 may be a battery module, a battery bank, or a set of battery cells (cell-to-pack structure).

The sensor unit 14 may obtain information related to the battery unit 12, such as values related to a state of each battery cell 10. For example, the values related to the states may include one or more values of voltages, currents, resistances, SOC, SOH, or temperatures of a battery cell or combinations thereof. The sensor unit 14 may provide information about each of the plurality of battery cells 10 to the BMS 20.

The switching unit 16 may include a component for controlling a current flow associated with charging or discharging of the battery unit 12. For example, the switching unit 16 may include at least one relay and/or magnetic contactor according to the specifications of the battery pack 1.

The BMS 20 may be an interface for monitoring a voltage, a current, and/or a temperature of the battery pack 1 to control or manage the battery pack 1 for preventing over-charging and/or over-discharging. For example, the BMS 20 may include a plurality of terminals and/or circuits to process input values. The BMS 20 may control the sensor unit 14 and/or the switching unit 16. For example, the BMS 20 may be connected to the battery unit 12 to monitor a state of each of the plurality of battery cells 10 and turn on or off a relay or a contactor based on the state of each of the plurality of battery cells 10. Operations of the BMS 20 may be performed in not only a BMS of a vehicle but also various devices external to the vehicle, such as a server, a cloud, a charger, and/or a charger/discharger, as examples. A higher-level controller 2 may transmit a control signal regarding the battery unit 12 to the BMS 20. Thus, the BMS 20 may be controlled based on signals applied from the higher-level controller 2.

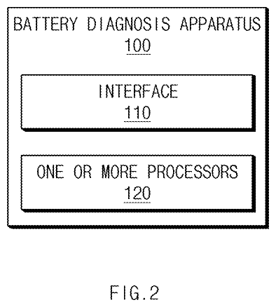

The BMS 20 may include a battery diagnosis apparatus, such as the battery diagnosis apparatus 100 of FIG. 2. Alternatively, or additionally, the battery diagnosis apparatus 100 of FIG. 2 may be included in the battery pack 1 and/or may be configured as another device external to the battery pack 1. The operations of the battery diagnosis apparatus 100 may also be performed in various devices, including not only a battery management system (BMS) in a vehicle, but also a server, a cloud, a charger, and/or a charger/discharger.

FIG. 2 is a block diagram of a battery diagnosis apparatus 100 according to aspects of the disclosure. The battery diagnosis apparatus 100 may diagnose a state of a battery cell 10. For example, the battery cell 10 may have a defect, such as defects at the production stage, internal deformation and denaturation through charging and discharging, and/or external shock. The defect may include tab disconnection, electrode failure, and/or lithium precipitation in the battery cell 10. The battery diagnosis apparatus 100 may diagnose an abnormality in the battery cell 10 based on an impedance measured in the battery cell 10.

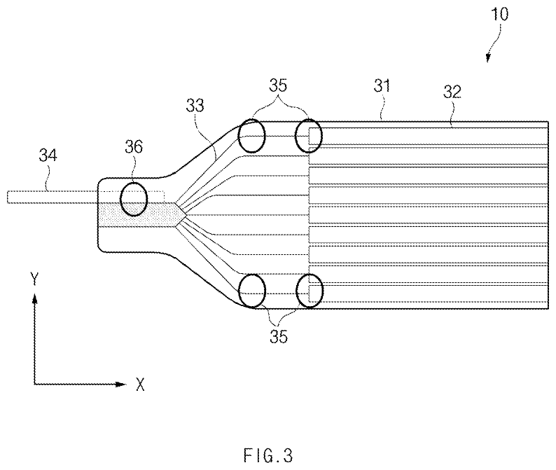

FIG. 3 is a diagram showing an inner side of a battery cell 10 according to aspects of the disclosure. An electrode assembly 32 may be included in a battery case 31 of the battery cell 10. The electrode assembly 32 may extend in an X-axis direction that is a longitudinal direction of the battery cell 10 and may be stacked in a Y-axis direction that is a height direction of the battery cell 10. Electrode tabs 33 may protrude from the electrode assembly 32 in the X-axis direction, and the plurality of electrode tabs 33 may be connected to an electrode lead 34.

A welding portion between the electrode assembly 32 and the electrode tab 33, a welding portion between the electrode tab 33 and the electrode lead 34, the electrode tab 33, or the electrode lead 34 may be deformed by various physical and chemical external forces applied during manufacturing and/or use of the battery cell 10 and may have a defect. The defect may mean a defect, e.g., lithium precipitation, of the electrode assembly 32, disconnection 35 of the electrode tab 33, and/or a failure 36 of the electrode lead 34. The defect of the battery cell 10 may cause an abnormality such as under-voltage, charging/discharging performance degradation and/or ignition of the battery cell 10. Thus, when a defect occurs in the battery cell 10, an abnormal battery cell may show a resistance pattern that is different from that of a normal battery cell.

The battery diagnosis apparatus 100 may detect an abnormality of the battery cell 10 based on an impedance variance measured when voltage is applied to the battery cell 10. An impedance variance of a battery cell may mean an impedance variance of a battery cell with respect to a frequency. The battery diagnosis apparatus 100 may detect an abnormality of the battery cell 10 based on an impedance measured at a plurality of measurement points of the electrode lead 34 of the battery cell 10. The plurality of measurement points may mean two or more measurement points in at least one of a first electrode, e.g., a positive electrode, and a second electrode, e.g., a negative electrode, of the electrode lead 34. The battery diagnosis apparatus 100 may detect an abnormal behavior of the impedance variance based on the impedance measured at the plurality of measurement points and diagnose the abnormal battery cell.

Referring back to FIG. 2, the battery diagnosis apparatus 100 may include an interface 110 and one or more processors 120. However, the battery diagnosis apparatus 100 may further include other components, two or more components may be integrated into one component, and/or one component may be divided into two or more components.

The interface 110 may obtain impedance data measured from the electrode lead 34 of an inspection target battery cell. The interface 110 may mean a component that is capable of wiredly and/or wirelessly communicating with an external device. For example, the interface 110 may obtain impedance data by communicating with an impedance measurement device, e.g., an electrochemical impedance spectroscopy (EIS) measurement device. The interface 110 may obtain the impedance data by communicating with other components such as the BMS 20, the server, and/or the cloud.

The inspection target battery cell may be the battery cell 10 of a pouch type and/or may mean a bidirectional battery cell in which the electrode leads 34 having different polarities are derived from opposite ends of the battery cell 10 in the longitudinal direction. Alternatively, or additionally, the inspection target battery cell may also mean a unidirectional battery cell in which the electrode leads 34 having different polarities are derived from the same end of the battery cell.

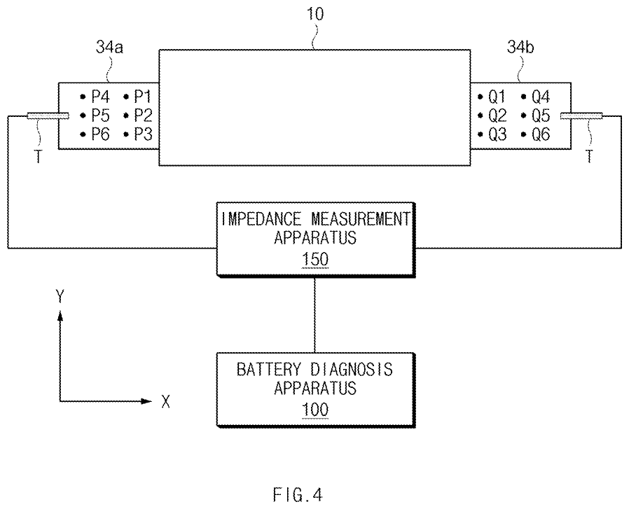

FIG. 4 is a diagram showing a method of measuring an impedance of an electrode lead of a battery cell according to aspects of the disclosure. An impedance measurement device 150 may be connected to the electrode lead 34 of the inspection target battery cell 10 to measure the impedance of the inspection target battery cell 10. The impedance measurement device 150 may be connected to the electrode lead 34 of the battery cell 10 by predetermined connection cable and connection terminal. For example, the impedance measurement device 150 may be connected to a first electrode lead 34a and a second electrode lead 34b through a pair of probes T.

The impedance measurement device 150 may measure the impedance of the battery cell 10 with respect to a frequency. For example, the impedance measurement device 150 may mean an EIS measurement device. The impedance measurement device 150 may apply a small alternating current (AC) signal and/or AC voltage signal to the inspection target battery cell 10 while changing a frequency and measure a current and/or voltage signal output from the inspection target battery cell 10 in response to the applied signal to obtain a frequency-specific impedance. The EIS measurement device 150 may obtain various parameters related to an impedance such as a phase angle, resistance, and/or reactance of the impedance as well as the impedance with respect to a frequency.

The electrode leads 34a and 34b of the inspection target battery cell 10 may include a plurality of measurement points P1 to P6 and Q1 to Q6. For example, the first electrode lead 34a may include the plurality of measurement points P1 to P6, and the second electrode lead 34b may include the plurality of measurement points Q1 to Q6. While each of the electrode leads 34a and 34b include 6 measurement points in FIG. 4, each of the electrode leads 34a and 34b may include n measurement points corresponding to positions on each electrode lead, where n is a natural number greater than or equal to 1.

The measurement device 150 may measure an impedance between one of the plurality of measurement points P1 to P6 of the first electrode lead 34a and one of the plurality of measurement points Q1 to Q6 of the second electrode lead 34b. For example, when each of the electrode leads 34a and 34 b includes 6 measurement points as shown in FIG. 4, the impedance measurement device 150 may measure 36 different impedances.

When at least one of the plurality of electrode tabs 33 is disconnected, a measured impedance may be high as a measurement point of the electrode leads 34a and 34b are close to a portion where the electrode tab 33 is disconnected. The electrode leads 34a and 34b may be connected to the plurality of electrode tabs 33. Thus, when disconnection occurs in a specific electrode tab, an impedance measured at a measurement point close to an electrode tab where disconnection occurs may be higher than an impedance measured at a measurement point close to a normal electrode tab. For example, when the electrode tab 33 closest to the first point P1 is disconnected, an impedance between the first point P1 of the first electrode lead 34a and the first point Q1 of the second electrode lead 34b may be higher than that between another point, e.g., P2 or P3 of the first electrode lead 34a and another point, e.g., Q2 or Q3 of the second electrode lead 34b.

Thus, when the battery diagnosis apparatus 100 diagnoses an abnormality of the battery cell 10 by using the impedance measured at one measurement point of the electrode leads 34a and 34b, the battery diagnosis apparatus 100 may misdiagnose the abnormal battery cell as a normal battery cell, resulting in a lower accuracy. However, the battery diagnosis apparatus 100 obtaining an impedance measured at a plurality of measurement points may more accurately diagnose the state of the battery cell based on the obtained impedance. The battery diagnosis apparatus 100 may improve the accuracy of diagnosis by diagnosing the state of the battery cell 10 based on a plurality of impedances.

The interface 110 may obtain a frequency-specific impedance between, for example, each of the plurality of measurement points P1 and P2 of the first electrode lead 34a and, for example, a single measurement point Q2 of the second electrode lead 34b of the inspection target battery cell 10. Alternatively, or additionally, the interface 110 may obtain a first impedance Z1 that is a frequency-specific impedance of an AC voltage applied between the first point P1 of the first electrode lead 34a and the measurement point Q2 of the second electrode lead 34b. The interface 110 may obtain a second impedance Z2 that is a frequency-specific impedance of an AC voltage applied between the second point P2 of the first electrode lead 34a and the measurement point Q2 of the second electrode lead 34b.

For one measurement point, e.g., Q2 of the second electrode lead 34b, Y-axis positions of a plurality of measurement points, e.g., P1, P3, and P5 of the first electrode lead 34a may be different from each other. Herein, the Y-axis direction may mean a second direction intersecting the first direction in which the first electrode lead 34a protrudes from the battery cell 10. Thus, the first point P1 of the first electrode lead 34a and the second point P2 of the first electrode lead 34a may be spaced apart from each other in the second direction. Alternatively, or additionally, when one measurement point, e.g., Q2 of the second electrode lead 34b is fixed, the plurality of measurement points, e.g., P1, P3, and P5, of the first electrode lead 34a may not be positioned along the same straight line in the X-axis direction. In this way, the battery diagnosis apparatus 100 may accurately diagnose a point on the Y-axis at which the electrode tab 33 having disconnection occurring is positioned in the electrode tabs 33 stacked in the Y-axis direction.

When the measurement point, e.g., Q2 of the second electrode lead 34b is the same, the plurality of measurement points, e.g., P1, P2, and P3, of the first electrode lead 34a may be positioned along a straight line in the Y-axis direction. The plurality of measurement points may include at least two of the first point P1, the second point P2, and/or the third point P3. For example, the first point P1, the second point P2, and the third point P3 may be positioned along a straight line in the second direction intersecting the first direction in which the first electrode lead 34a protrudes from the battery cell 10. Thus, when the first point is P1, the second point may be P2 and the third point may be P3; when the first point is P4, the second point may be P5 and the third point may be P6. In this way, the battery diagnosis apparatus 100 may accurately diagnose a point on the Y-axis at which the electrode tab 33 having disconnection occurring is positioned in the electrode tabs 33 stacked in the Y-axis direction.

The first point P1, the second point P2, and the third point P3 may be positioned apart from each other by a predetermined distance. The first point P1 may be spaced apart from the second point P2 by a first interval in the second direction, and the third point may be spaced apart from the second point P2 by the first interval in a direction opposite to the second direction. In this way, the battery diagnosis apparatus 100 may compare impedances measured at the first point and the third point spaced above and below from the second point among the plurality of measurement points by the first interval to accurately diagnose a point on the Y-axis at which the electrode tab 33 having disconnection occurring is positioned. The battery diagnosis apparatus 100 may more accurately diagnose the state of the battery cell based on impedance variances, e.g., deviations, including an impedance variance between the first point and the second point, an impedance variance between the second point and the third point, and an impedance variance between the first point and the third point.

Referring to FIGS. 2 and 4, the one or more processors 120 may perform operations of the battery diagnosis apparatus 100. For example, the one or more processors 120 may diagnose the state of the battery cell 10 by processing data obtained from the interface 110. The one or more processors 120 may determine, based on the impedance data with respect to the frequency obtained from the interface 110, whether the battery cell 10 is abnormal and diagnose the state.

The one or more processors 120 may diagnose the state of the battery cell 10 based on the impedance and the impedance variance. The impedance may be an impedance measured at a fixed specific point, e.g., Q2 of the second electrode lead 34b and an impedance measured at each of the plurality of measurement points, e.g., P1 and P2 of the first electrode lead 34a. The impedance variance may mean a difference between the above-described impedances.

For example, the one or more processors 120 may diagnose the state of the battery cell 10, based on a first impedance Z1 between the first point P1 among the plurality of measurement points and a specific point, e.g., Q2 of the second electrode lead 34b, a second impedance Z2 between the second point P2 among the plurality of measurement points and a specific point, e.g., Q2 of the second electrode lead 34b, and a first impedance variance Z_12 that is a difference between the first impedance Z1 and the second impedance Z2.

The one or more processors 120 may compare each of the first impedance Z1,the second impedance Z2, and the first impedance variance Z_12 with a predetermined threshold value. The predetermined threshold value may refer to an impedance measured at a normal battery cell and mean a reference value for distinguishing a normal battery cell from an abnormal battery cell. For example, the predetermined threshold value may include a threshold value for the first impedance Z1, a threshold value for the second impedance Z2, and a threshold value for the first impedance variance Z_12.

The one or more processors 120 may determine the predetermined threshold value based on an impedance measured at a measurement point of a normal battery cell corresponding to each of the plurality of measurement points of the inspection target battery cell 10. For example, the one or more processors 120 may determine the predetermined threshold value based on a frequency-specific impedance between the first point P1 of the normal battery cell corresponding to the first point P1 of the inspection target battery cell 10 and a measurement point of the normal battery cell corresponding to the measurement point of the second electrode lead 34b of the inspection target battery cell 10. The predetermined threshold value may mean a range of impedances of the normal battery cell with respect to a frequency. For example, the predetermined threshold value may mean a maximum value or a minimum value of the normal battery cell with respect to a frequency. In this way, the one or more processors 120 may diagnose a battery cell having a higher impedance than the normal battery cell as an abnormal battery cell.

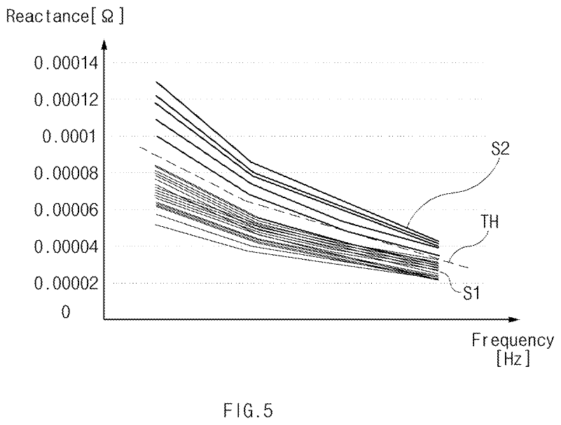

FIG. 5 is a graph showing frequency vs reactance for diagnosing an abnormal battery cell according to aspects of the disclosure. The one or more processors 120 may calculate impedance-related parameters with respect to a frequency and diagnose a state of the battery cell 10 based on one or more parameters. The impedance-related parameters may mean a phase angle, a resistance, and/or a reactance of an impedance, as examples.

The one or more processors 120 may calculate a resistance and a reactance of each of the first impedance Z1, the second impedance Z2, and the first impedance variance Z_12 and compare at least one of the resistance and the reactance with a predetermined threshold value TH to diagnose the state of the battery cell 10. The predetermined threshold value TH may mean a reference value for distinguishing a normal battery cell S1 from an abnormal battery cell S2. For example, the predetermined threshold value TH may mean a resistance or a reactance calculated based on an impedance measured in the normal battery cell S1. In this way, the battery diagnosis apparatus 100 may diagnose the abnormal battery cell S2 based on at least one of a resistance, which is a real part, and a reactance, which is an imaginary part, of the impedance. Even when the abnormal battery cell S2 is not diagnosed based on the resistance, the battery diagnosis apparatus 100 may diagnose the abnormal battery cell S2 based on the reactance, thus improving the accuracy of diagnosis.

When at least one of the first impedance Z1, the second impedance Z2, and the first impedance variance Z_12 is greater than the predetermined threshold value TH, the one or more processors 120 may diagnose the battery cell 10 as being in an abnormal state. Thus, the battery diagnosis apparatus 100 may improve the accuracy of the diagnosis by further comparing the first impedance variance Z_12 with the threshold value TH in comparison to comparing the first impedance Z1 or the second impedance Z2 with the threshold value TH. For example, when the first impedance Z1 and the second impedance Z2 are in a normal range below the threshold value, but the first impedance variance Z_12 is greater than the threshold value, the battery diagnosis apparatus 100 may diagnose an abnormality of the battery cell and improve the accuracy of the diagnosis. In this way, the battery diagnosis apparatus 100 may diagnose the state of the battery cell 10 based on an impedance measured at one measurement point, thereby solving a problem of misdiagnosing the abnormal battery cell S2 as the normal battery cell S1.

When the plurality of measurement points of the first electrode lead 34a are three measurement points, the one or more processors 120 may diagnose the state of the battery cell 10 based on the impedance, measured at the plurality of measurement points, and the impedance variance. The impedance may be an impedance measured at a fixed specific point, e.g., Q2 of the second electrode lead 34b and an impedance measured at each of the plurality of measurement points, e.g., P1, P2, and P3 of the first electrode lead 34a. The impedance variance may mean a difference between the above-described impedances.

For example, the one or more processors 120 may diagnose the state of the battery cell 10 based on the first impedance Z1, the second impedance Z2, the third impedance Z3, the first impedance variance Z_12, a second impedance variance Z_23, and a third impedance variance Z_31. The third impedance Z3 may mean an impedance between the third point P3 and the second electrode lead 34b, the second impedance variance Z_23 may mean a difference between the second impedance Z2 and the third impedance Z3, and the third impedance variance Z_31 may mean a difference between the first impedance Z1 and the third impedance Z3. In this way, the battery diagnosis apparatus 100 may more accurately diagnose the state of the battery cell 10 by further considering the third impedance Z3, the second impedance variance Z_23, and the third impedance variance Z_31 when using three measurement points in comparison to when using two measurement points.

The one or more processors 120 may diagnose a position where a defect occurs in the inspection target battery cell 10 based on a sign of an impedance variance. The defect may include tab disconnection, electrode failure, and/or lithium precipitation in the battery cell 10, as examples.

For example, when the plurality of measurement points of the first electrode lead 34a are two measurement points and disconnection occurs in the electrode tab 33 closest to the first point P1, the first impedance Z1 may be greater than the second impedance Z2. Thus, the first impedance variance Z_12, which is a difference of the second impedance Z2 from the first impedance Z1, may be a positive number. In this way, when the first impedance variance Z_12 is a positive number, the one or more processors 120 may diagnose tab disconnection occurring at the first point P1 of the inspection target battery cell 10.

On the other hand, when disconnection occurs in the electrode tab 33 closest to the second point P2, the first impedance Z1 may be less than the second impedance Z2. Thus, the first impedance variance Z_12, which is the difference of the second impedance Z2 from the first impedance Z1, may be a negative number. In this way, when the first impedance variance Z_12 is a negative number, the one or more processors 120 may diagnose tab disconnection occurring at the second point P2 of the inspection target battery cell 10. Thus, the battery diagnosis apparatus 100 may not only diagnose whether the inspection target battery cell 10 is an abnormal battery cell or a normal battery cell, but also diagnose a correct position in the abnormal battery cell in which a defect occurs.

The one or more processors 120 may diagnose a degree of the defect based on a magnitude of the impedance or a magnitude of the impedance variance. The magnitude of the impedance may mean a value obtained by adding a square of the real part of the impedance and a square of the imaginary part of the impedance and then taking a square root. For example, as any one of the magnitude of the first impedance Z1, the magnitude of the second impedance Z2, and the magnitude of the first impedance variance Z_12 is greater than the predetermined threshold value, the one or more processors 120 may diagnose that the degree of the defect occurring in the inspection target battery cell 10 is great. The degree of the defect may mean a length of electrode tab disconnection, an area of an electrode failure, and/or an amount of lithium precipitation inside the battery cell 10.

The one or more processors 120 may diagnose the degree of the defect based on the resistance or reactance of the impedance. For example, as the resistance or reactance of the impedance is greater than the predetermined threshold value, the one or more processors 120 may diagnose that the degree of the defect occurring in the inspection target battery cell 10 is great. The predetermined threshold value may mean a reference value for distinguishing a normal battery cell from an abnormal battery cell.

As the length of disconnection of the electrode tab 33 increases, the magnitude of the impedance may tend to increase. For example, as the length of disconnection increases, the resistance may increase. Thus, the battery diagnosis apparatus 100 may diagnose the length of disconnection based on the magnitude of the impedance.

When the battery cell 10 is diagnosed as having abnormality as a result of diagnosis, the battery diagnosis apparatus 100 may provide information about an abnormal battery cell to a user. For example, the one or more processors 120 may provide information about an abnormal battery cell to a user terminal through a communication circuit (not shown) and provide the information about the abnormal battery cell through a display provided in a vehicle, a charger, etc.

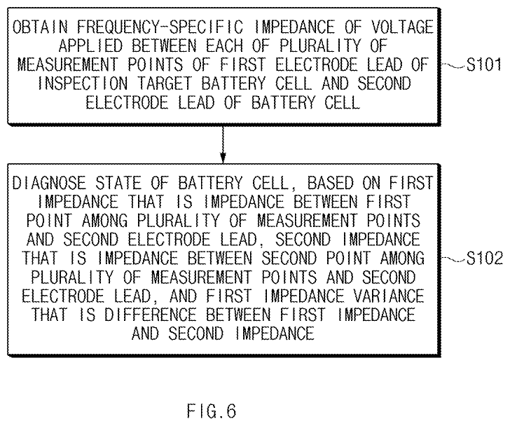

FIG. 6 is a flowchart of an operation of a battery diagnosis apparatus according to aspects of the disclosure. The battery diagnosis apparatus 100 may obtain a frequency-specific impedance of a voltage applied between each of a plurality of measurement points of a first electrode lead of an inspection target battery cell and a second electrode lead of the battery cell in operation S101, and diagnose a state of the battery cell based on a first impedance that is an impedance between a first point among the plurality of measurement points and the second electrode lead, a second impedance that is an impedance between a second point among the plurality of measurement points and the second electrode lead, and a first impedance variance that is a difference between the first impedance and the second impedance in operation S102.

In operation S101, the battery diagnosis apparatus 100 obtains the impedance with respect to the frequency of the voltage applied between each of the plurality of measurement points of the first electrode lead of the inspection target battery cell and the second electrode lead of the battery cell. The battery diagnosis apparatus 100 may obtain impedance data from the impedance measurement apparatus 150 or the BMS 20.

In operation S102, the battery diagnosis apparatus 100 diagnoses the state of the battery cell based on the first impedance, the second impedance, and the first impedance variance. When the plurality of measurement points of the first electrode lead are three measurement points, the battery diagnosis apparatus 100 may diagnose the state of the battery cell further based on the third impedance that is an impedance between the third point among the plurality of measurement points and the second electrode lead, the second impedance variance that is a difference between the second impedance and the third impedance, and the third impedance variance that is a difference between the first impedance and the third impedance.

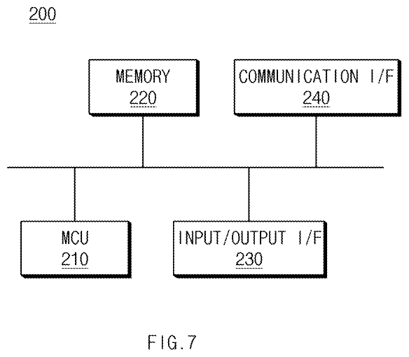

FIG. 7 is a block diagram showing a hardware configuration of a computing system 200 for performing an operating method of a battery diagnosis apparatus according to aspects of the disclosure. The computing system 200 may include an MCU 210, a memory 220, an input/output I/F 230, and a communication I/F 240.

The MCU 210 may be a processor that executes various programs, e.g., a battery cell data collection program, a graph calculation program, a data analysis program, a data decomposition algorithm, a normalization program, and/or a battery cell diagnosis program, stored in the memory 220, that processes various information including feature data and/or potential variables, of the battery cell through these programs, and executes the above-described functions of the battery diagnosis apparatus 100 shown in FIG. 4.

The memory 220 may store various programs, such as a battery cell data collection program, a graph calculation program, a data analysis program, a data decomposition algorithm, a normalization program, and/or a battery cell diagnosis program. The memory 220 may store operation data of the battery diagnosis apparatus 100.

The memory 220 may be one or more memories. The memory 220 may be volatile memory or non-volatile memory. For the memory 220 as the volatile memory, random access memory (RAM), dynamic RAM (DRAM), static RAM (SRAM), etc., may be used. For the memory 220 as the nonvolatile memory, read only memory (ROM), programmable ROM (PROM), electrically alterable ROM (EAROM), erasable PROM (EPROM), electrically erasable PROM (EEPROM), flash memory, etc., may be used. The memory 2200 may be a transitory or non-transitory computer readable medium. As such, a computer program according to an embodiment disclosed herein may be recorded in the memory 220 and processed by the MCU 210, thus being implemented as a module that performs functions shown in FIG. 2.

The input/output I/F 230 may provide an interface for transmitting and receiving data by connecting an input device (not shown) such as a keyboard, a mouse, and/or a touch panel, and an output device (not shown), such as a display, to the MCU 210.

The communication I/F 240 may be configured to transmit and receive various data to and from a server and may be capable of supporting wired or wireless communication. For example, the battery diagnosis apparatus 100 may transmit and receive various information including a shape model of the battery cell from an external server separately provided through the communication I/F 240.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible implementations. Further, the same reference numbers in different drawings can identify the same or similar elements.

1. A battery diagnosis apparatus comprising one or more processors configured to:
obtain a frequency-specific impedance of a voltage applied between each of a plurality of measurement points of a first electrode lead of an inspection target battery cell and a second electrode lead of the battery cell; and
diagnose a state of the battery cell, based on a first impedance that is an impedance between a first point among the plurality of measurement points and the second electrode lead, a second impedance that is an impedance between a second point among the plurality of measurement points and the second electrode lead, and a first impedance variance that is a difference between the first impedance and the second impedance.

2. The battery diagnosis apparatus of claim 1, wherein the first point and the second point are spaced apart from each other in a second direction intersecting a first direction in which the first electrode lead protrudes from the battery cell.

3. The battery diagnosis apparatus of claim 2, wherein the first point and the second point are positioned along a straight line in the second direction.

4. The battery diagnosis apparatus of claim 1, wherein the one or more processors are further configured to:
compare the first impedance, the second impedance, and the first impedance variance with respective predetermined threshold values; and
diagnose the battery cell as being in an abnormal state when at least one of the first impedance, the second impedance, or the first impedance variance is greater than its respective predetermined threshold value.

5. The battery diagnosis apparatus of claim 4, wherein the one or more processors are further configured to determine the respective predetermined threshold values based on the frequency-specific impedance measured at each of a first point of a normal battery cell corresponding to the first point and a second point of the normal battery cell corresponding to the second point.

6. The battery diagnosis apparatus of claim 1, wherein the one or more processors are further configured to diagnose the state of the battery cell, based on a third impedance that is an impedance between a third point among the plurality of measurement points and the second electrode lead, a second impedance variance that is a difference between the second impedance and the third impedance, and a third impedance variance that is a difference between the first impedance and the third impedance.

7. The battery diagnosis apparatus of claim 6, wherein the first point is spaced from the second point by a first interval in a second direction intersecting a first direction in which the first electrode lead protrudes from the battery cell and
the third point is spaced from the second point by the first interval in a direction opposite to the second direction.

8. The battery diagnosis apparatus of claim 1, wherein the one or more processors are further configured to diagnose a position where a defect occurs in the inspection target battery cell based on a sign of the first impedance variance.

9. The battery diagnosis apparatus of claim 8, wherein the one or more processors are further configured to:
diagnose that the defect occurs at the first point in the inspection target battery cell, based on the first impedance variance being a positive number; and
diagnose that the defect occurs at the second point in the inspection target battery cell based on the first impedance variance being a negative number.

10. The battery diagnosis apparatus of claim 1, wherein the one or more processors are further configured to diagnose that a degree of the defect occurring in the inspection target battery cell based on at least one of a magnitude of the first impedance, a magnitude of the second impedance, or a magnitude of the first impedance variance.

11. An operating method of a battery diagnosis apparatus, the operating method comprising:
obtaining a frequency-specific impedance of a voltage applied between each of a plurality of measurement points of a first electrode lead of an inspection target battery cell and a second electrode lead of the battery cell; and
diagnosing a state of the battery cell, based on a first impedance that is an impedance between a first point among the plurality of measurement points and the second electrode lead, a second impedance that is an impedance between a second point among the plurality of measurement points and the second electrode lead, and a first impedance variance that is a difference between the first impedance and the second impedance.

12. The operating method of claim 11, wherein the first point and the second point are spaced apart from each other in a second direction intersecting a first direction in which the first electrode lead protrudes from the battery cell.

13. The operating method of claim 12, wherein the first point and the second point are positioned along a straight line in the second direction.

14. The operating method of claim 11, wherein the diagnosing comprises:
comparing the first impedance, the second impedance, and the first impedance variance with respective predetermined threshold values; and
diagnosing the battery cell as being in an abnormal state when at least one of the first impedance, the second impedance, or the first impedance variance is greater than its respective predetermined threshold value.

15. The operating method of claim 14, wherein the diagnosing comprises determining the respective predetermined threshold values based on the frequency-specific impedance measured at each of a first point of a normal battery cell corresponding to the first point and a second point of the normal battery cell corresponding to the second point.

16. The operating method of claim 11, wherein the diagnosing is further based on a third impedance that is an impedance between a third point among the plurality of measurement points and the second electrode lead, a second impedance variance that is a difference between the second impedance and the third impedance, and a third impedance variance that is a difference between the first impedance and the third impedance.

17. The operating method of claim 16, wherein the first point is spaced from the second point by a first interval in a second direction intersecting a first direction in which the first electrode lead protrudes from the battery cell and
the third point is spaced from the second point by the first interval in a direction opposite to the second direction.

18. The operating method of claim 11, wherein the diagnosing comprises diagnosing a position where a defect occurs in the inspection target battery cell based on a sign of the first impedance variance.

19. (canceled)

20. The operating method of claim 14, wherein the diagnosing comprises diagnosing that a degree of the defect occurring in the inspection target battery cell based on at least one of a magnitude of the first impedance, a magnitude of the second impedance, or a magnitude of the first impedance variance.

21. A non-transitory computer readable medium for storing instructions that, when executed by one or more processors, cause the one or more processors to perform a method of a battery diagnosis apparatus, the method comprising:
obtaining a frequency-specific impedance of a voltage applied between each of a plurality of measurement points of a first electrode lead of an inspection target battery cell and a second electrode lead of the battery cell; and
diagnosing a state of the battery cell based on a first impedance that is an impedance between a first point among the plurality of measurement points and the second electrode lead, a second impedance that is an impedance between a second point among the plurality of measurement points and the second electrode lead, and a first impedance variance that is a difference between the first impedance and the second impedance.
